(19) United States
(12) Patent Application Publication
(10) Pub. No.: US 2024/0206161 A1
(43) Pub. Date: Jun. 20, 2024

(54) SEMICONDUCTOR MEMORY DEVICE AND METHOD OF MANUFACTURING SEMICONDUCTOR MEMORY DEVICE

(71) Applicant: Kioxia Corporation, Tokyo (JP)

(72) Inventor: Takuto IKEYAMA, Yokkaichi (JP)

(73) Assignee: Kioxia Corporation, Tokyo (JP)

(21) Appl. No.: 18/535,221

(22) Filed: Dec. 11, 2023

(30) Foreign Application Priority Data
Dec. 19, 2022 (JP) 2022-202347

(51) Int. Cl. H10B 41/30; H10B 41/10; H10B 41/20; H10B 43/10; H10B 43/20; H10B 43/30

(52) U.S. Cl. CPC H10B 41/30; H10B 41/10; H10B 41/20; H10B 43/10; H10B 43/20; H10B 43/30

(57) ABSTRACT

In a semiconductor memory device according to an embodiment, when viewed in a cross section along a second direction, first to third regions are arrayed in the second direction and each of the first to third regions has a plurality of terrace surfaces having different height positions, in the first and second regions, the height positions of the plurality of terrace surfaces are arranged in line-symmetry with respect to a plate-like portion dividing the first and second regions among the plurality of plate-like portions, and in the second and third regions, the height positions of the plurality of terrace surfaces are arranged in line-asymmetry with respect to a plate-like portion dividing the second and third regions among the plurality of plate-like portions.

### CROSS-REFERENCE TO RELATED APPLICATIONS

This application is based upon and claims the benefit of priority from Japanese Patent Application No. 2022-202347, filed on Dec. 19, 2022; the entire contents of which are incorporated herein by reference.

### FIELD

Embodiments described herein relate generally to a semiconductor memory device and a method of manufacturing the semiconductor memory device.

### BACKGROUND

In a three-dimensional nonvolatile memory, for example, a part of a stacked body in which a plurality of conductive layers is stacked is processed into a stepped shape, and each of the conductive layers is drawn out to an upper layer interconnection. A stepped portion having such a stepped structure is formed by lithography and etching. At this time, correction is performed by lithography so as to suppress a dimensional conversion difference. However, with an increase in the number of stacked conductive layers, a limit of correction by lithography is being reached.

### BRIEF DESCRIPTION OF THE DRAWINGS

FIG. 1 is a sectional view illustrating a configuration of a semiconductor memory device according to an embodiment;

FIGS. 2A to 2C are schematic diagrams including a cross section of a stepped portion of the semiconductor memory device according to the embodiment in a Y direction;

FIGS. 3A to 3C are schematic diagrams including a cross section of the stepped portion of the semiconductor memory device according to the embodiment in the Y direction;

FIGS. 4A to 4Gb are schematic diagrams including a cross section of the stepped portion of the semiconductor memory device according to the embodiment in an X direction;

FIGS. 5A to 5D are sectional views along the Y direction sequentially exemplifying a part of a procedure of a method of manufacturing the semiconductor memory device according to the embodiment;

FIGS. 6A to 6D are sectional views along the Y direction sequentially exemplifying a part of the procedure of the method of manufacturing the semiconductor memory device according to the embodiment;

FIGS. 7A to 7F are sectional views along the Y direction sequentially exemplifying a part of the procedure of the method of manufacturing the semiconductor memory device according to the embodiment;

FIGS. 8A to 8D are sectional views along the Y direction sequentially exemplifying a part of the procedure of the method of manufacturing the semiconductor memory device according to the embodiment;

FIGS. 9A and 9B are top views of a stacked body for describing a correction example of a mask pattern used at a time of forming GY steps according to the embodiment;

FIGS. 10A to 10D are sectional views in the Y direction illustrating an example of a procedure of a method of forming GY steps according to a comparative example; and

FIGS. 11A to 11E are sectional views sequentially exemplifying a part of the procedure of a method of manufacturing a semiconductor memory device according to a modification of the embodiment.

### DETAILED DESCRIPTION

A semiconductor memory device according to an embodiment includes a stacked body in which a plurality of conductive layers and a plurality of insulating layers are alternately stacked one by one, a stepped portion in which the plurality of conductive layers is processed into a stepped shape, and a plurality of plate-like portions that extends in the stacked body in a stacking direction of the stacked body and a first direction intersecting the stacking direction and divides the stacked body and the stepped portion of the stacked body in a second direction intersecting the stacking direction and the first direction, in which the stepped portion includes first to third regions that are divided by the plurality of plate-like portions and are adjacent in an order of the first to third regions in the second direction, and when viewed in a cross section along the second direction, each of the first to third regions has a plurality of terrace surfaces arrayed in the second direction and having different height positions, in the first and second regions, the height positions of the plurality of terrace surfaces are arranged in line-symmetry with respect to a plate-like portion dividing the first and second regions among the plurality of plate-like portions, and in the second and third regions, the height positions of the plurality of terrace surfaces are arranged in line-asymmetry with respect to a plate-like portion dividing the second and third regions among the plurality of plate-like portions.

Hereinafter, an embodiment of the present invention will be described in detail with reference to the drawings. Note that the present invention is not limited by the following embodiment. In addition, constituent elements in the following embodiment include those that can be easily assumed by those skilled in the art or those that are substantially the same.

### Configuration Example of Semiconductor Memory Device

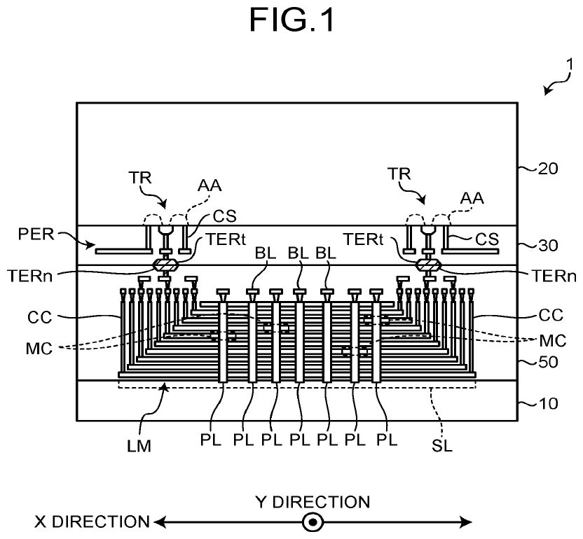

FIG. 1 is a sectional view along an X direction illustrating a configuration of a semiconductor memory device 1 according to an embodiment. However, in FIG. 1, hatching is omitted in consideration of visibility of the drawing.

In the present specification, both the X direction and a Y direction are directions along a direction of a surface of a word line to be described later, and the X direction and the Y direction are orthogonal to each other. An electrical drawing direction of a word line to be described later may be referred to as a first direction, and the first direction is a direction along the X direction. A direction intersecting the first direction may be referred to as a second direction, and the second direction is a direction along the Y direction. However, since the semiconductor memory device 1 can include a manufacturing error, the first direction and the second direction are not necessarily orthogonal to each other.

As illustrated in FIG. 1, the semiconductor memory device 1 includes a stacked body LM and a peripheral circuit PER.

The stacked body LM has a structure in which a plurality of word lines is stacked on a source line SL with an insulating layer interposed therebetween. The semiconductor memory device 1 may include a support substrate 10 that supports the stacked body LM. In this case, the support substrate 10 may be a semiconductor substrate, a ceramic substrate, a glass substrate, or the like, and the source line SL is disposed on a surface layer of the support substrate. When the support substrate 10 is a semiconductor substrate, the source line SL may be a diffusion layer or the like in which impurities of the surface layer of the support substrate 10 are diffused.

At both ends in the X direction of the stacked body LM, the word lines are processed into a stepped shape, and a contact CC is connected to each step of the word lines. An upper end of the contact CC is connected to an upper layer interconnection or the like via a plug. The upper layer interconnection is further connected to a terminal TERn via a plug. The terminal TERn includes, for example, copper (Cu).

In the stacked body LM, a plurality of pillars PL that penetrates the stacked body LM in a stacking direction and reaches the source line SL is arranged in a matrix. Each of the pillars PL includes a memory layer and a channel layer. The channel layer of the pillar PL has a lower end connected to the source line SL and an upper end connected to a bit line BL via a plug or the like. A memory cell MC is formed at an intersection between the pillar PL and the word line of the stacked body LM.

In this manner, the semiconductor memory device 1 is configured as, for example, a three-dimensional nonvolatile memory including the memory cells MC arranged three-dimensionally.

The stacked body LM, the contact CC, the plug, the upper layer interconnection, the bit line BL, and the like are covered with an insulating layer 50. The terminal TERn is exposed on an upper surface of the insulating layer 50.

The peripheral circuit PER includes a plurality of transistors TR formed on a semiconductor substrate 20, and controls an electrical operation of the plurality of memory cells MC. The transistor TR is, for example, a complementary metal oxide semiconductor (CMOS) transistor or the like, and has an active region AA which is a diffusion layer or the like disposed on a surface layer of the semiconductor substrate 20.

The transistor TR is connected to the upper layer interconnection via the contact CS. The upper layer interconnection is further connected to a terminal TERt via a plug. The terminal TERt includes, for example, copper (Cu).

The peripheral circuit PER including the transistor TR and the like, the contact CS, the plug and the like are covered with an insulating layer 30. The terminal TERt is exposed on an upper surface of the insulating layer 30.

The semiconductor memory device 1 has a configuration in which the insulating layer 50 covering the stacked body LM and the insulating layer 30 covering the peripheral circuits PER are joined. As a result, the terminal TERn exposed on the upper surface of the insulating layer 50 and the terminal TERt exposed on the upper surface of the insulating layer 30 are joined.

In this manner, the configuration of the pillars PL, the contacts CC, and the like of the stacked body LM and the peripheral circuit PER are electrically conducted via the terminals TERn and TERt. The peripheral circuit PER controls a write operation, a read operation, and the like of the memory cell MC, for example, by applying a predetermined voltage to the word line of the stacked body LM connected to the memory cell MC.

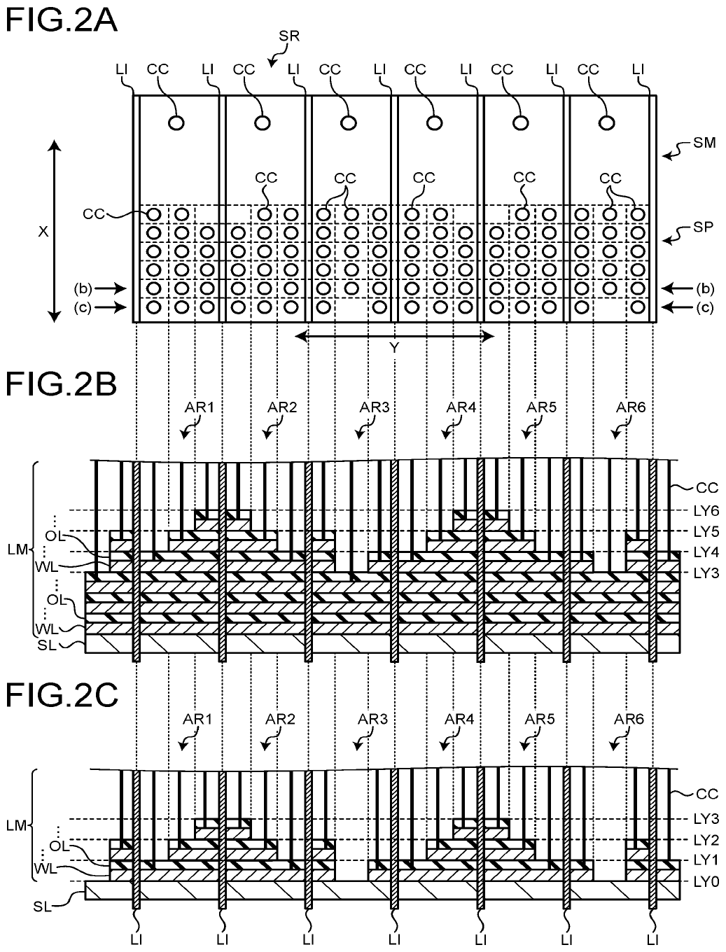

Next, the configuration of the stepped portion SP of the semiconductor memory device 1 will be described with reference to FIGS. 2A to 4Gb.

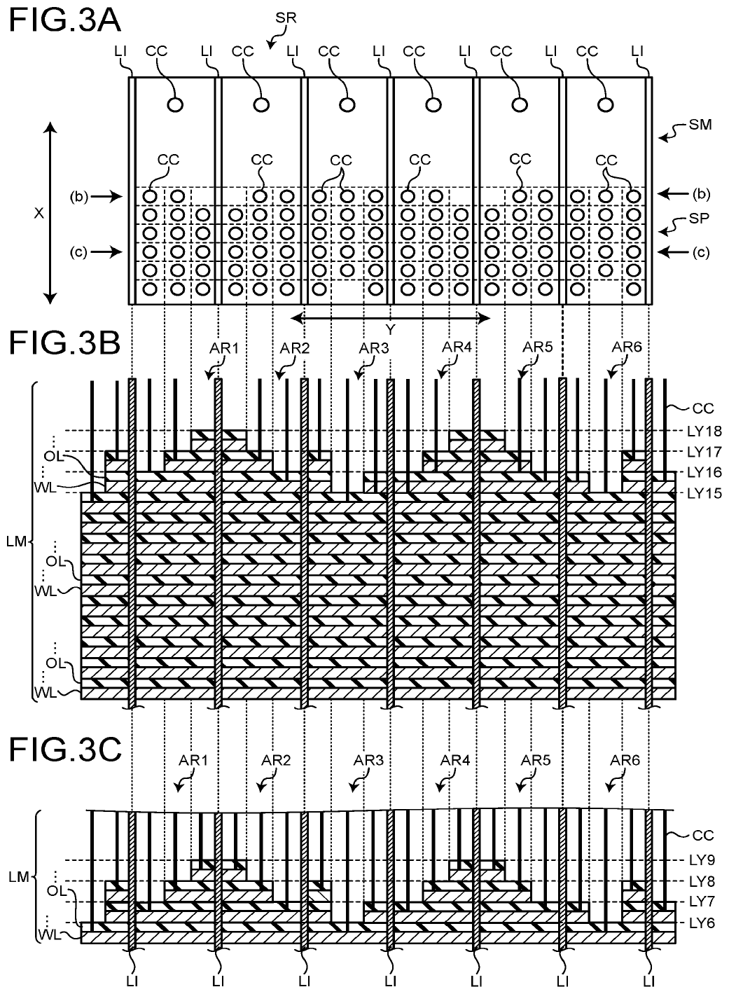

FIGS. 2A to 3C are schematic diagrams including a cross section of the stepped portion SP of the semiconductor memory device 1 according to the embodiment in the Y direction. FIGS. 2A and 3A are top views of the stepped region SR, and FIGS. 2B, 2C, 3B, and 3C are sectional views of the stepped portion SP along the Y direction. In the top view of FIG. 2A, the lower side in the plane of the drawing is an end in the X direction of the stacked body LM, and the upper side in the plane of the drawing is a central portion of the stacked body LM in which the pillars PL (see FIG. 1) are disposed.

As illustrated in FIGS. 2A to 2C, the stacked body LM included in the semiconductor memory device 1 is disposed on the source line SL and has a structure in which a plurality of word lines WL and a plurality of insulating layers OL are alternately stacked one by one. Each of the word lines WL as a plurality of conductive layers is, for example, a tungsten layer, a molybdenum layer, or the like. Each of the plurality of insulating layers OL is, for example, a silicon oxide layer or the like.

In the stacked body LM, a plurality of plate-like contacts LI extending in the stacking direction of the stacked body LM and the X direction is disposed. The plate-like contacts LI as a plurality of plate-liked portions extend in the X direction at predetermined intervals in the Y direction. As a result, the stacked body LM is divided into a plurality of parts in the Y direction by the plurality of plate-like contacts LI.

Each of the plate-like contacts LI includes an insulating layer (not illustrated) on a side wall, and includes a conductive layer (not illustrated) filled further inside the insulating layer. As a result, the plate-like contact LI functions as a source line contact electrically connected to the source line SL. However, instead of the plate-like contact LI, the stacked body LM may be divided in the Y direction by the plate-like portion entirely filled with the insulating layer.

The stacked body LM includes the stepped region SR at the end in the X direction. The stepped region SR includes the stepped portion SP, an upper step portion SM, and the plurality of contacts CC.

The stepped portion SP has a shape in which the plurality of word lines WL and the plurality of insulating layers OL are processed into a stepped shape in the X direction and the Y direction. In the stepped portion SP, one pair or a plurality of pairs of the word lines WL and the insulating layers OL form one step with one word line WL and the insulating layer OL immediately above the word line WL as a pair. Thus, a plurality of terrace surfaces having different height positions are disposed in the X direction and the Y direction.

In the X direction, the terrace surfaces of the stepped portion SP are higher from the end in the X direction of the stacked body LM toward the central portion. At this time, the terrace surface of each of the steps adjacent in the X direction is different in height position in the stacking direction of the stacked body LM by three layers of the word lines WL, that is, three pairs of the word lines WL and the insulating layers OL. That is, in each of the steps adjacent in the X direction, when an n-th word line WL from a lowermost layer of the stacked body LM is an uppermost word line WL on a lower layer side, a (n+3)-th word line WL from the lowermost layer is an uppermost word line WL on an upper layer side. A portion extending in the X direction of the stepped portion SP in this manner is also referred to as GX steps or the like.

In the Y direction, the stepped portion SP includes three terrace surfaces having different heights in each region between the plate-like contacts LI adjacent in the Y direction. At this time, the terrace surface included in one region between the plate-like contacts LI is different in height by one layer of the word line WL, that is, by a pair of the word line WL and the insulating layer OL. That is, one region between the plate-like contacts LI includes three steps in which the n-th, (n+1)-th, and (n+2)-th word lines WL from the lowermost layer of the stacked body LM are the uppermost layers. A portion extending in the Y direction of the stepped portion SP in this manner is also referred to as GY steps or the like.

As described above, the contacts CC are respectively disposed on the plurality of terrace surfaces having different height positions disposed in the stepped portion SP in the X direction and the Y direction. Specifically, each of the contacts CC penetrates the insulating layer OL constituting each terrace surface and is connected to the word line WL adjacent to the insulating layer OL of the terrace surface below in the stacking direction.

The upper step portion SM of the stepped region SR is disposed closer to the central portion of the stacked body LM than the stepped portion SP. The contact CC connected to the uppermost word line WL is disposed in each region of the upper step portion SM sandwiched by the plate-like contacts LI adjacent in the Y direction.

Note that, in the present specification, the direction in which the terrace surface of the stepped portion SP faces is defined as the upper side of the semiconductor memory device 1. Although each terrace surface of the stepped portion SP is substantially configured by the insulating layer OL, in the present specification, the word line WL immediately below to be connected to the contact CC may also be included in the configuration forming the terrace surface.

FIG. 2C is a sectional view taken along the Y direction at a position indicated by arrow (c) in FIG. 2A. That is, FIG. 2C illustrates a cross section of a lowermost step of the stepped portion SP.

As illustrated in FIG. 2C, the regions of the stacked body LM sandwiched between the plate-like contacts LI adjacent in the Y direction are referred to as regions AR1 to AR6 in order from the left side of the plane of the drawing. In addition, an upper surface of the source line SL below the stacked body LM is referred to as a level LY0, a first pair of the word line WL and the insulating layer OL from the lowermost layer is referred to as a level LY1, and hereinafter, a second pair, a third pair, and the like are referred to as levels LY2, LY3, and the like. The terrace surface including the first pair of the word line WL and the insulating layer OL from the lowermost layer is referred to as a terrace surface of the level LY1, and thereafter, the terrace surfaces including the second pair, the third pair, and the like of the word line WL and the insulating layer OL are referred to as terrace surfaces of the levels LY2, LY3, and the like, respectively.

In the region AR1, three terrace surfaces having different heights, that is, the terrace surfaces of the levels LY1, LY2, and LY3 are included in that order toward the region AR2. In the region AR2, the terrace surfaces of the levels LY3, LY2, and LY1 are included in that order from the region AR1 toward the region AR3. In the region AR3, the terrace surfaces of the levels LY2, LY0, and LY1 are included in that order from the region AR2 toward the region AR4.

In the region AR4, the terrace surfaces of the levels LY1, LY2, and LY3 are included in that order from the region AR3 toward the region AR5. In the region AR5, the terrace surfaces of the levels LY3, LY2, and LY1 are included in that order from the region AR4 toward the region AR6. In the region AR6, the terrace surfaces of the levels LY1, LY0, and LY2 are included in that order in a direction away from the region AR5.

Note that contacts CC respectively connected to the word lines WL on the terrace surfaces are disposed on the terrace surfaces of the levels LY1 to LY3 disposed at the lowermost step in the X direction of the stepped portion SP. However, the terrace surface of the level LY0 is a surface from which the source line SL below the stacked body LM is exposed, and does not have the word line WL to be connected. Therefore, the contact CC is not disposed on the terrace surface of the level LY0.

As described above, the arrangement of the height positions of the plurality of terrace surfaces is equal in the region AR1 and the region AR4, and such arrangement of the terrace surfaces is repeated for every three regions arrayed in the Y direction. The arrangement of the height positions of the plurality of terrace surfaces is equal in the region AR2 and the region AR5, and such arrangement of the terrace surfaces is also repeated for every three regions arrayed in the Y direction.

Furthermore, in the regions AR3 and AR6, the height positions of the plurality of terrace surfaces are arranged in line-symmetry across, for example, the regions AR4 and AR5 located between the regions AR3 and AR6. The arrangement of the terrace surface of the region AR3 and the arrangement of the terrace surface of the region AR6 are alternately repeated for every three regions arrayed in the Y direction.

Therefore, in the regions AR1 and AR2, the height positions of the plurality of terrace surfaces are arranged in line-symmetry with respect to the plate-like contact LI dividing the regions AR1 and AR2. In the region adjacent to the region AR1 on an opposite side of the region AR2 and in the regions AR1 to AR3, the height positions of the plurality of terrace surfaces are arranged in line-symmetry with respect to the plate-like contact LI dividing the regions AR1 and AR2. In this manner, the regions in which the terrace surfaces are arranged in line-symmetry with each other extend on both sides in the X direction with the plate-like contact LI dividing the regions AR1 and AR2 as a center.

In the regions AR4 and AR5, the height positions of the plurality of terrace surfaces are arranged in line-symmetry with respect to the plate-like contact LI dividing the regions AR4 and AR5. In the regions AR3 to AR6, the height positions of the plurality of terrace surfaces are arranged line-symmetry with respect to the plate-like contact LI dividing the regions AR4 and AR5. In this manner, the regions in which the terrace surfaces are arranged in line-symmetry with each other extend on both sides in the X direction with the plate-like contact LI dividing the regions AR4 and AR5 as the center.

On the other hand, in a plurality of sets of regions deviated from the regions AR1 and AR2 or the regions AR4 and AR5, the height positions of the plurality of terrace surfaces are arranged in line-asymmetry with each other. That is, in the regions AR2 and AR3, for example, the height positions of the plurality of terrace surfaces are arranged in line-asymmetry with respect to the plate-like contact LI dividing the regions AR2 and AR3. Similarly, in the regions AR3 and AR4, for example, the height positions of the plurality of terrace surfaces are arranged in line-asymmetry with respect to the plate-like contact LI dividing the regions AR3 and AR4. In the regions AR5 and AR6, for example, the height positions of the plurality of terrace surfaces are arranged in line-asymmetry with respect to the plate-like contact LI dividing the regions AR5 and AR6.

The arrangement of the terrace surface of the stepped portion SP in the Y direction is also maintained at each step of the GY steps where the height position of the terrace surface increases in the X direction.

FIG. 2B is a sectional view taken along the Y direction at a position indicated by arrow (b) in FIG. 2A. That is, FIG. 2B illustrates a cross section of a second step from the lowermost step of the stepped portion SP.

As illustrated in FIG. 2B, since the arrangement the terrace surface of the stepped portion SP in the Y direction is also maintained in the cross section of the second step from the lowermost step, the plurality of terrace surfaces included in the regions AR1 to AR6 has the height position of the level on an upper layer side by three levels from the level of the corresponding terrace surface of the lowermost step.

That is, in the region AR1, the terrace surfaces of the levels LY4, LY5, and LY6 are included in that order toward the region AR2. In the region AR2, the terrace surfaces of the levels LY6, LY5, and LY4 are included in that order from the region AR1 toward the region AR3. In the region AR3, the terrace surfaces of the levels LY5, LY3, and LY4 are included in that order from the region AR2 toward the region AR4.

In the region AR4, the terrace surfaces of the levels LY4, LY5, and LY6 are included in that order from the region AR3 toward the region AR5. In the region AR5, the terrace surfaces of the levels LY6, LY5, and LY4 are included in that order from the region AR4 toward the region AR6. In the region AR6, the terrace surfaces of the levels LY4, LY3, and LY5 are included in that order in a direction away from the region AR5.

Note that contacts CC respectively connected to the word lines WL on the terrace surfaces are disposed on the terrace surfaces of the levels LY3 to LY6 disposed at the lowermost step in the X direction of the stepped portion SP.

FIG. 3C is a sectional view taken along the Y direction at a position indicated by arrow (c) in FIG. 3A. That is, FIG. 3C illustrates a cross section of the third step from the lowermost step of the stepped portion SP. Note that FIG. 3A is a top view of the stepped region SR, and is the same as FIG. 2A. In FIG. 3C, the word line WL and the insulating layer OL on the lower layer side of the level LY6 are not illustrated.

As illustrated in FIG. 3C, since the arrangement of the terrace surface of the stepped portion SP in the Y direction is also maintained in the cross section of the third step from the lowermost step, the plurality of terrace surfaces included in the regions AR1 to AR6 has the height position of the level on an upper layer side by three levels from the level of the corresponding terrace surface of the second step from the lowermost step illustrated in FIG. 2B.

That is, in the region AR1, the terrace surfaces of the levels LY7, LY8, and LY9 are included in that order toward the region AR2. In the region AR2, the terrace surfaces of the levels LY9, LY8, and LY7 are included in that order from the region AR1 toward the region AR3. In the region AR3, the terrace surfaces of the levels LY8, LY6, and LY7 are included in that order from the region AR2 toward the region AR4.

In the region AR4, the terrace surfaces of the levels LY7, LY8, and LY9 are included in that order from the region AR3 toward the region AR5. In the region AR5, the terrace surfaces of the levels LY9, LY8, and LY7 are included in that order from the region AR4 toward the region AR6. In the region AR6, the terrace surfaces of the levels LY7, LY6, and LY8 are included in that order in a direction away from the region AR5.

Note that contacts CC respectively connected to the word lines WL on the terrace surfaces are disposed on the terrace surfaces of the levels LY6 to LY9 disposed at the lowermost step in the X direction of the stepped portion SP.

FIG. 3B is a sectional view taken along the Y direction at a position indicated by arrow (b) in FIG. 3A. That is, FIG. 3B illustrates a cross section of an uppermost step of the stepped portion SP. Note that, in FIG. 3B, the word line WL and the insulating layer OL on the lower layer side of the level LY6 are also not illustrated.

As illustrated in FIG. 3B, the arrangement of the terrace surface of the stepped portion SP in the Y direction is also maintained in the cross section of the uppermost step. In the example of FIGS. 2A to 3C, six GX steps are provided in the X direction from the lowermost step to the uppermost step. As a result, the plurality of terrace surfaces included in the regions AR1 to AR6 has the height position of the level on an upper layer side by nine levels from the level of the corresponding terrace surface of the third step from the lowermost step illustrated in FIG. 3C.

That is, in the region AR1, the terrace surfaces of the levels LY16, LY17, and LY18 are included in that order toward the region AR2. In the region AR2, the terrace surfaces of the levels LY18, LY17, and LY16 are included in that order from the region AR1 toward the region AR3. In the region AR3, the terrace surfaces of the levels LY17, LY15, and LY16 are included in that order from the region AR2 toward the region AR4.

In the region AR4, the terrace surfaces of the levels LY16, LY17, and LY18 are included in that order from the region AR3 toward the region AR5. In the region AR5, the terrace surfaces of the levels LY18, LY17, and LY16 are included in that order from the region AR4 toward the region AR6. In the region AR6, the terrace surfaces of the levels LY16, LY15, and LY17 are included in that order in a direction away from the region AR5.

Note that contacts CC respectively connected to the word lines WL on the terrace surfaces are disposed on the terrace surfaces of the levels LY15 to LY17 disposed at the lowermost step in the X direction of the stepped portion SP. However, in the example of FIGS. 2A to 3C, the terrace surface of the level LY18 includes the uppermost word line WL and insulating layer OL of the stacked body LM. The contact connected to the uppermost word line WL is disposed in the upper step portion SM for each of the regions AR1 to AR6 divided by the plurality of plate-like contacts LI. Therefore, the contact CC is not disposed on the terrace surface of the level LY18 of the stepped portion SP.

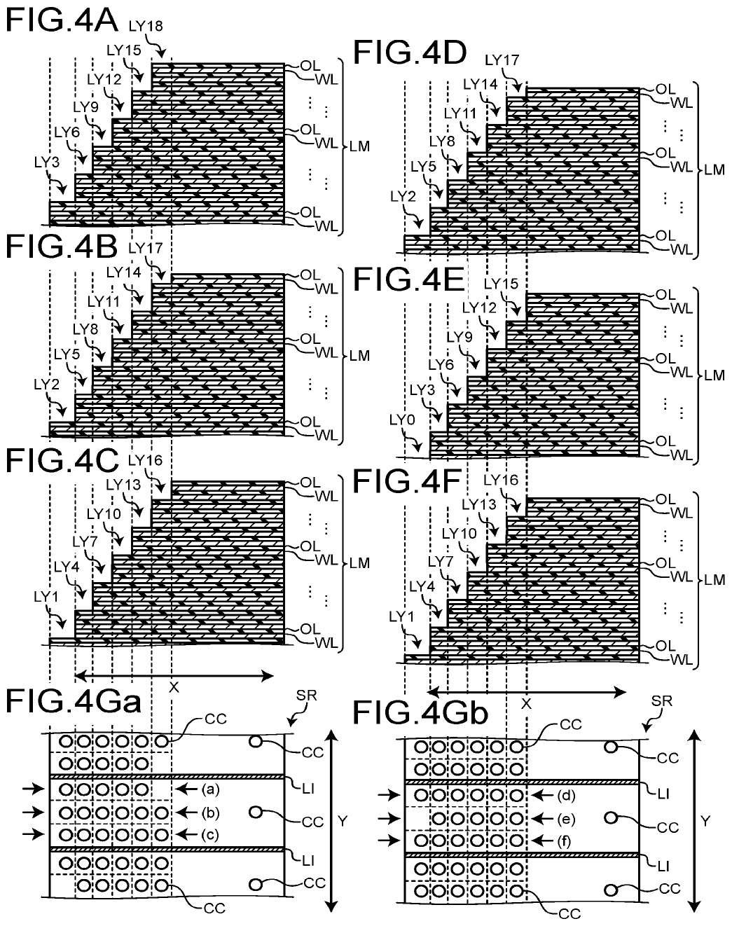

Such a configuration of the stepped portion SP enables each of the plurality of word lines WL stacked in multiple steps to be electrically drawn. Here, as described above, the stacked body LM is divided in the Y direction by the plurality of plate-like contacts LI. Therefore, for each of the regions AR1 to AR6 of the stepped portion SP sandwiched between the plurality of plate-like contacts LI, the contact CC is disposed on each of the terrace surfaces of the second level LY17 of the uppermost layer from the level LY1 of the lowermost layer. This state is illustrated in FIGS. 4A to 4Gb.

FIGS. 4A to 4Gb are schematic diagrams including a cross section of the stepped portion SP of the semiconductor memory device 1 according to the embodiment in the X direction.

FIGS. 4A to 4D are diagrams illustrating different cross sections of the stepped portion SP in the X direction. FIGS. 4Ga and 4Gb are top views of the stepped region SR including different regions in FIGS. 2A and 3A, respectively.

Specifically, FIG. 4Ga is a top view including the region AR1 or the region AR4 in FIGS. 2A to 3C, and FIG. 4Gb is a top view including the region AR3 in FIGS. 2A to 3C. FIGS. 4A to 4C are sectional views of the three terrace surfaces arrayed in the Y direction in the region AR1 or the region AR4 illustrated in FIG. 4Ga. FIGS. 4D to 4F are sectional views of the three terrace surfaces arrayed in the Y direction in the region AR3 illustrated in FIG. 4Gb.

FIG. 4A is a sectional view taken along the X direction at a position indicated by arrow (a) in FIG. 4Ga. As illustrated in FIG. 4A, in this cross section, the GX steps extending in the X direction have the terrace surfaces of the levels LY3, LY6, LY9, LY12, LY15, and LY18 from a lower step side toward an upper step side.

FIG. 4B is a sectional view taken along the X direction at a position indicated by arrow (b) in FIG. 4Ga. As illustrated in FIG. 4B, in this cross section, the GX steps extending in the X direction have the terrace surfaces of the levels LY2, LY5, LY8, LY11, LY14, and LY17 from the lower step side toward the upper step side.

FIG. 4C is a sectional view taken along the X direction at a position indicated by arrow (c) in FIG. 4Ga. As illustrated in FIG. 4C, in this cross section, the GX steps extending in the X direction have the terrace surfaces of the levels LY1, LY4, LY7, LY10, LY13, and LY16 from the lower step side toward the upper step side.

In this manner, since the height positions of the three terrace surfaces arrayed in the Y direction gradually increase in the X direction, the terrace surfaces of all the word lines WL of the levels LY1 to LY18 included in the stacked body LM are included in the region AR1 or the region AR4.

Among the terrace surfaces of the levels LY1 to LY18, the contact CC is disposed on each of the terrace surfaces of the levels LY1 to LY17 of the stepped portion SP as described above, and the contact CC connected to the uppermost word line WL is disposed in the upper step portion SM corresponding to the region AR1 or the region AR4. Therefore, all the word lines WL in the stacked body LM can be electrically drawn out to the upper layer interconnection in the region AR1 or the region AR4 divided by the plurality of plate-like contacts LI.

The configuration of the stepped portion SP in which the three GX steps are disposed in one region divided by the plate-like contact LI in this manner is also referred to as a three-row steps or the like. By adopting a structure of a plurality of rows of steps such as a three-row steps in which a plurality of GX steps is disposed in one region, the length of the stepped portion SP in the X direction can be shortened.

FIG. 4D is a sectional view taken along the X direction at a position indicated by arrow (d) in FIG. 4Gb. As illustrated in FIG. 4D, in this cross section, the GX steps extending in the X direction have the terrace surfaces of the levels LY2, LY5, LY8, LY11, LY14, and LY17 from the lower step side toward the upper step side.

FIG. 4E is a sectional view taken along the X direction at a position indicated by arrow (e) in FIG. 4Gb. As illustrated in FIG. 4E, in this cross section, the GX steps extending in the X direction have the terrace surfaces of the levels LY0, LY3, LY6, LY9, LY12, and LY15 from the lower step side toward the upper step side.

FIG. 4F is a sectional view taken along the X direction at a position indicated by arrow (f) in FIG. 4Gb. As illustrated in FIG. 4F, in this cross section, the GX steps extending in the X direction have the terrace surfaces of the levels LY1, LY4, LY7, LY10, LY13, and LY16 from the lower step side toward the upper step side.

In this manner, since the height positions of the three terrace surfaces arrayed in the Y direction gradually increase in the X direction, the terrace surfaces of the word lines WL of the levels LY1 to LY17 included in the stacked body LM are included in the region AR3.

The contact CC is disposed on each of the terrace surfaces of the levels LY1 to LY17 of the stepped portion SP as described above, and the contact CC connected to the uppermost word line WL is disposed in the upper step portion SM corresponding to the region AR3. Therefore, all the word lines WL in the stacked body LM can be electrically drawn out to the upper layer interconnection in the region AR3 divided by the plurality of plate-like contacts LI.

As described above, the regions AR2, AR3, and AR6 other than the regions described above are line-symmetric in the Y direction with respect to the regions AR1, AR4, and AR3 described above, respectively. Therefore, as in the regions AR1, AR4, and AR3, the terrace surfaces of the word lines WL of at least the levels LY1 to LY17 are included in the regions AR2, AR3, and AR6.

Therefore, by arranging the contact CC connected to the uppermost word line WL on the terrace surfaces of the regions AR2, AR3, and AR6 and the upper step portion SM corresponding to the regions AR2, AR3, and AR6, all the word lines WL in the stacked body LM can be electrically drawn out to the upper layer interconnection in each of the regions AR2, AR3, and AR6 divided by the plurality of plate-like contacts LI.

### Method of Manufacturing Semiconductor Memory Device

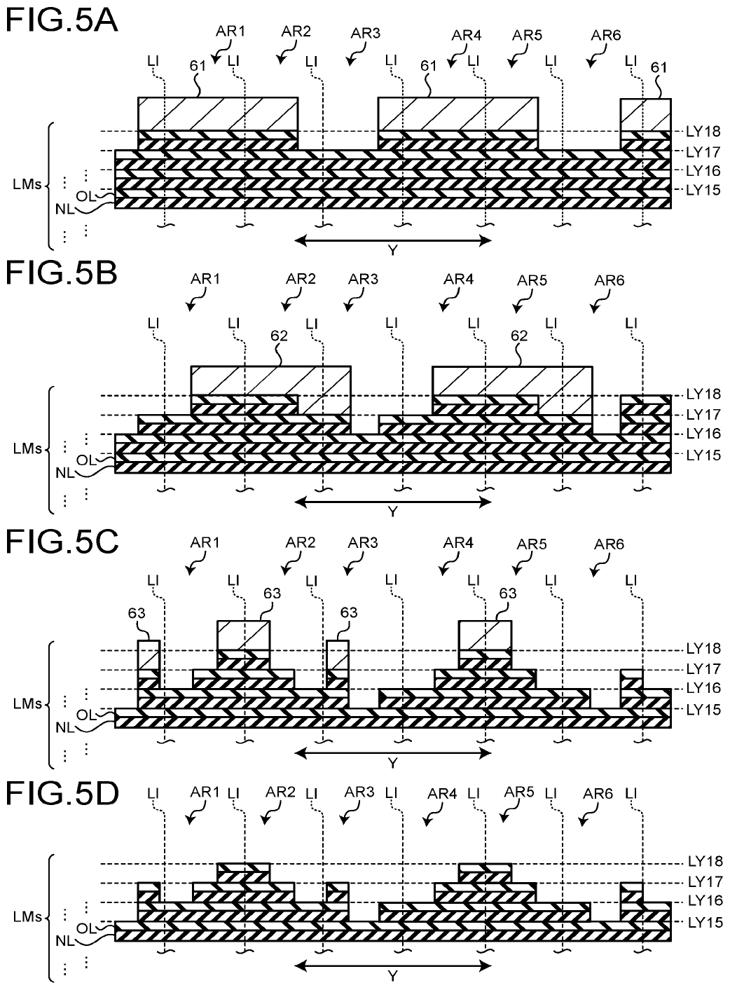

Next, an example of a method of manufacturing the semiconductor memory device 1 according to the embodiment will be described with reference to FIGS. 5A to 9B.

FIGS. 5A to 8D are sectional views along the Y direction sequentially exemplifying a part of the procedure of the method of manufacturing the semiconductor memory device 1 according to the embodiment; In FIGS. 5A to 8D, an example of a method of forming the stepped portion SP will be mainly described.

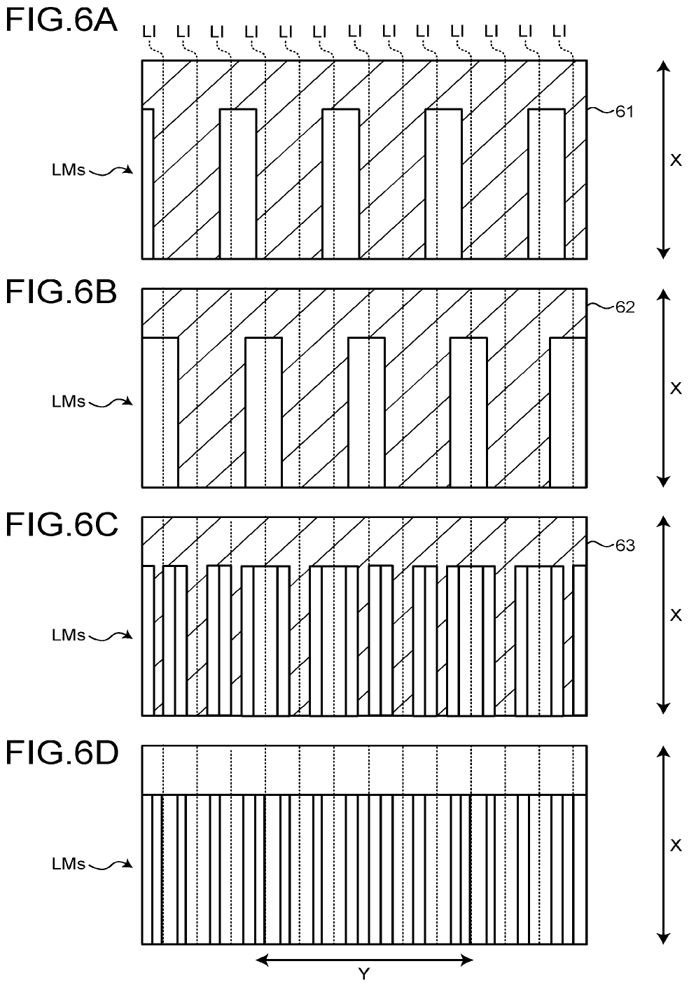

First, an example of a method of forming the GY steps will be described with reference to FIGS. 5A to 6D. FIGS. 5A to 5D are sectional views along the Y direction of a formation region of the stepped portion SP. FIGS. 6A to 6D are top views of the formation region of the stepped portion SP.

Although the plate-like contact LI is not formed at the time point illustrated in FIGS. 5A to 6D, the plate-like contact LI is indicated by a broken line for convenience of description. In addition, FIGS. 5A to 5D illustrate configurations from the uppermost level LY18 to the lower level LY15. Prior to the processing illustrated in FIGS. 5A to 6D, the source line SL is formed on the substrate.

As illustrated in FIG. 5A, a stacked body LMs in which a plurality of insulating layers NL as first insulating layers and a plurality of insulating layers OL as second insulating layers are alternately stacked one by one is formed on the source line SL. The insulating layer NL is a sacrificial layer such as a silicon nitride layer, for example, and is replaced with a conductive material or the like in a later process to become the word line WL.

As illustrated in FIGS. 5A and 6A, a mask pattern 61 as a first mask pattern is formed on the stacked body LMs. The mask pattern 61 covers a region where the pillar PL and the like of the stacked body LMs are formed. In a region where the stepped portion SP is to be formed, the mask patterns 61 extend in the X direction at predetermined intervals in the Y direction. Such a mask pattern 61 includes, for example, an organic material such as a positive or negative resist layer, and is exposed by using extreme ultra-violet (EUV), KrF rays, or the like.

Specifically, the mask pattern 61 is formed across the regions AR3 to AR5, for example. At this time, the mask pattern 61 is formed to have a width corresponding to two of the regions AR3 to AR5 in the Y direction. The mask pattern 61 is formed such that a center position in the Y direction is shifted toward the region AR4 with respect to the plate-like contact LI to be formed at a boundary between the regions AR4 and AR5, that is, between the regions AR4 and AR5.

As a result, the mask pattern 61 formed across the regions AR3 to AR5 is formed at a boundary with the region AR4 on the region AR3 to have a width corresponding to one terrace surface in the Y direction, the width being a width that the stepped portion SP finally has. The mask pattern 61 is formed to cover the entire region AR4. The mask pattern 61 is formed at a boundary with the region AR4 on the region AR5 to have a width corresponding to two terrace surfaces in the Y direction.

Similarly, the mask pattern 61 includes the region AR2 and is formed across three regions arrayed in a direction opposite to the region AR3. In this case, the mask pattern 61 is formed to have a width corresponding to two of the three regions including the region AR2 in the Y direction. The mask pattern 61 is formed such that a center position in the Y direction is shifted toward the region AR1 with respect to the plate-like contact LI to be formed at a boundary between the regions AR1 and AR2, that is, between the regions AR1 and AR2.

As a result, the mask pattern 61 formed across the three regions including the region AR2 is formed at a boundary with the region AR1 on a region adjacent to the region AR1 on an opposite side of the region AR2 to have a width of one terrace surface in the Y direction. The mask pattern 61 is formed to cover the entire region AR1. The mask pattern 61 is formed at a boundary with the region AR1 on the region AR2 to have a width corresponding to two terrace surfaces in the Y direction.

In this manner, in the region where the stepped portion SP is formed, the mask pattern 61 is formed to have a periodic pattern in the Y direction.

A pair of insulating layers NL and OL belonging to the level LY18 is etched from a surface of the stacked body LMs exposed from the mask pattern 61 formed as described above. At this time, dry etching by plasma, wet etching by chemical liquid, or the like can be used for etching.

By the etching, the insulating layers NL and OL of the level LY18 are removed from a partial region of the regions AR2 and AR3, the regions AR5 and AR6, and the like between the mask patterns 61 having the periodic pattern in the Y direction, and the insulating layer OL belonging to the level LY17 is exposed. Thereafter, the mask pattern 61 is removed by ashing using oxygen plasma or the like.

As illustrated in FIGS. 5B and 6B, a mask pattern 62 as a second mask pattern is formed on the stacked body LMs. The mask pattern 62 covers a region where the pillar PL and the like of the stacked body LMs are formed, similarly to the mask pattern 61. In a region where the stepped portion SP is to be formed, the mask patterns 62 extend in the X direction at predetermined intervals in the Y direction at a slightly different position from the mask patterns 61.

Specifically, the mask pattern 62 is formed across the regions AR4 to AR6, for example. At this time, the mask pattern 62 is formed to have a width corresponding to two of the regions AR4 to AR6 in the Y direction. The mask pattern 62 is formed such that a center position in the Y direction is shifted toward the region AR5 with respect to the plate-like contact LI to be formed at a boundary between the regions AR4 and AR5, that is, between the regions AR4 and AR5.

As a result, the mask pattern 62 formed across the regions AR4 to AR6 is formed at a boundary with the region AR5 on the region AR4 to have a width corresponding to two terrace surfaces in the Y direction. The mask pattern 62 is formed to cover the entire region AR5. The mask pattern 62 is formed at a boundary with the region AR5 on the region AR6 to have a width corresponding to one terrace surface in the Y direction.

Similarly, the mask pattern 62 is formed across the regions AR1 to AR3, for example. In this case, the mask pattern 62 is also formed to have a width corresponding to two of the regions AR1 to AR3 in the Y direction. The mask pattern 62 is formed such that a center position in the Y direction is shifted toward the region AR2 with respect to the plate-like contact LI to be formed at a boundary between the regions AR1 and AR2, that is, between the regions AR1 and AR2.

As a result, the mask pattern 62 formed across the regions AR1 to AR3 is formed at a boundary with the region AR2 on the region AR1 to have a width corresponding to two terrace surfaces in the Y direction. The mask pattern 62 is formed to cover the entire region AR2. The mask pattern 62 is formed at a boundary with the region AR2 on the region AR3 to have a width corresponding to one terrace surface in the Y direction.

In this manner, in the region where the stepped portion SP is formed, the mask pattern 62 is also formed to have a periodic pattern in the Y direction.

A pair of insulating layers NL and OL is etched from a surface of the stacked body LMs exposed from the mask pattern 62 formed as described above.

At this time, the insulating layers NL and OL of the level LY18 are removed from a partial region newly exposed after the formation of the mask pattern 62 in the regions AR3, AR4, and the like between the mask patterns 62 having the periodic pattern in the Y direction, and the insulating layer OL belonging to the level LY17 is exposed. In the regions AR3, AR4, and the like between the mask patterns 62, the insulating layers NL and OL of the level LY17 below the level LY18 are removed from a partial region from which the insulating layers NL and OL of the level LY18 have been removed by etching using the mask pattern 61, and the insulating layer OL belonging to the level LY16 is exposed.

As a result, two or three terrace surfaces having different heights are formed in each of the regions AR1 to AR6 and the like. At this time, for example, in the regions AR1 and AR2, the height positions of the plurality of terrace surfaces are arranged in line-symmetry with respect to the boundary of the regions AR1 and AR2. For example, in the regions AR4 and AR5, the height positions of the plurality of terrace surfaces are arranged in line-symmetry with respect to the boundary of the regions AR4 and AR5.

However, the width of the terrace surface in the Y direction at this time does not necessarily coincide with the width of the terrace surface in the Y direction that the stepped portion SP finally has. The terrace surface at this time has the same height over the entire region to be the stepped portion SP in the X direction.

Thereafter, the mask pattern 62 is removed by ashing using oxygen plasma or the like.

As illustrated in FIGS. 5C and 6C, mask patterns 63 as third to fifth mask patterns are formed on the stacked body LMs. The mask pattern 63 covers a region where the pillar PL and the like of the stacked body LMs are formed, similarly to the mask patterns 61 and 62. In a region where the stepped portion SP is to be formed, the mask patterns 63 extend in the X direction at predetermined intervals in the Y direction at a different position from the mask patterns 61 and 62.

Specifically, the mask pattern 63 as the third mask pattern is formed across the regions AR4 and AR5, for example. At this time, the mask pattern 63 is formed in a partial region of the regions AR4 and AR5 such that the center position in the Y direction coincides with a boundary between the regions AR4 and AR5, that is, the plate-like contact LI to be formed between the regions AR4 and AR5.

As a result, the mask pattern 63 formed across the regions AR4 and AR5 is formed at a boundary with the region AR5 on the region AR4 to have a width corresponding to one terrace surface in the Y direction, the width being a width that the stepped portion SP finally has. The mask pattern 63 is formed at a boundary with the region AR4 on the region AR5 to have a width corresponding to one terrace surface in the Y direction.

Similarly, the mask pattern 63 is formed across the regions AR1 and AR2, for example. At this time, the mask pattern 63 is formed in a partial region of the regions AR1 and AR2 such that the center position in the Y direction coincides with a boundary between the regions AR1 and AR2, that is, the plate-like contact LI to be formed between the regions AR1 and AR2.

As a result, the mask pattern 63 formed across the regions AR1 and AR2 is formed at a boundary with the region AR2 on the region AR1 to have a width corresponding to one terrace surface in the Y direction, the width being a width that the stepped portion SP finally has. The mask pattern 63 is formed at a boundary with the region AR1 on the region AR2 to have a width corresponding to one terrace surface in the Y direction.

In this manner, in the region where the stepped portion SP is formed, the mask pattern 63 as the third mask pattern is also formed to have a periodic pattern in the Y direction.

Furthermore, the mask pattern 63 as the fourth mask pattern is formed so as to cover, for example, a part of a region adjacent to the region AR1 opposite to the region AR2 on a side in contact with the region AR1. At this time, the mask pattern 63 is formed at a boundary with the region AR1 on the region described above to have a width corresponding to one terrace surface in the Y direction, the width being a width that the stepped portion SP finally has.

In the region where the stepped portion SP is formed, the mask pattern 63 as the fourth mask pattern is formed so as to have a periodic pattern in the Y direction for every other mask pattern 63 as the third mask pattern formed at the boundary of the regions AR1 and AR2, the boundary of the regions AR4 and AR5, and the like.

The mask pattern 63 as the fifth mask pattern is formed to cover, for example, a part of the region AR3 on a side in contact with the region AR2. At this time, the mask pattern 63 is formed at a boundary with the region AR2 on the region AR3 to have a width corresponding to one terrace surface in the Y direction, the width being a width that the stepped portion SP finally has.

In the region where the stepped portion SP is formed, the mask pattern 63 as the fifth mask pattern is also formed to have a periodic pattern in the Y direction for every other mask pattern 63 as the third mask pattern formed at the boundary of the regions AR1 and AR2, the boundary of the regions AR4 and AR5, and the like.

As a result, the mask patterns 63 as the fourth and fifth mask patterns are arranged in line-symmetry in the Y direction with respect to, for example, a boundary between the regions AR1 and AR2 where the mask pattern 63 as the third mask pattern is formed.

A pair of insulating layers NL and OL is etched from a surface of the stacked body LMs exposed from the mask pattern 63 formed as described above.

At this time, the insulating layers NL and OL of the level LY18 are removed from a partial region newly exposed after the formation of the mask pattern 63 in each region, and the like between the mask patterns 63 disposed at predetermined intervals in the Y direction, and the insulating layer OL belonging to the level LY17 is exposed.

In each region, and the like between the mask patterns 63, the insulating layers NL and OL of the level LY17 below the level LY18 are removed from a partial region from which the insulating layers NL and OL of the level LY18 have been removed by etching using the mask pattern 62, and the insulating layer OL belonging to the level LY16 is exposed.

In each region between the mask patterns 63, the insulating layers NL and OL of the level LY16 below the level LY17 are removed from a partial region from which the insulating layers NL and OL of the levels LY18 and LY17 have been removed by etching using the mask patterns 61 and 62, and the insulating layer OL belonging to the level LY15 is exposed.

As illustrated in FIGS. 5D and 6D, the mask pattern 63 is removed by ashing using oxygen plasma or the like. As a result, the shape of the GY steps that the stepped portion SP finally has is formed in a cross section along the Y direction. At this time, for example, in the regions AR1 and AR2, the arrangement of the height positions of the plurality of terrace surfaces line-symmetric with respect to the boundary of the regions AR1 and AR2 is maintained. However, as described above, at this stage, each terrace surface of the GY steps has the same height over the entire region to be the stepped portion SP in the X direction.

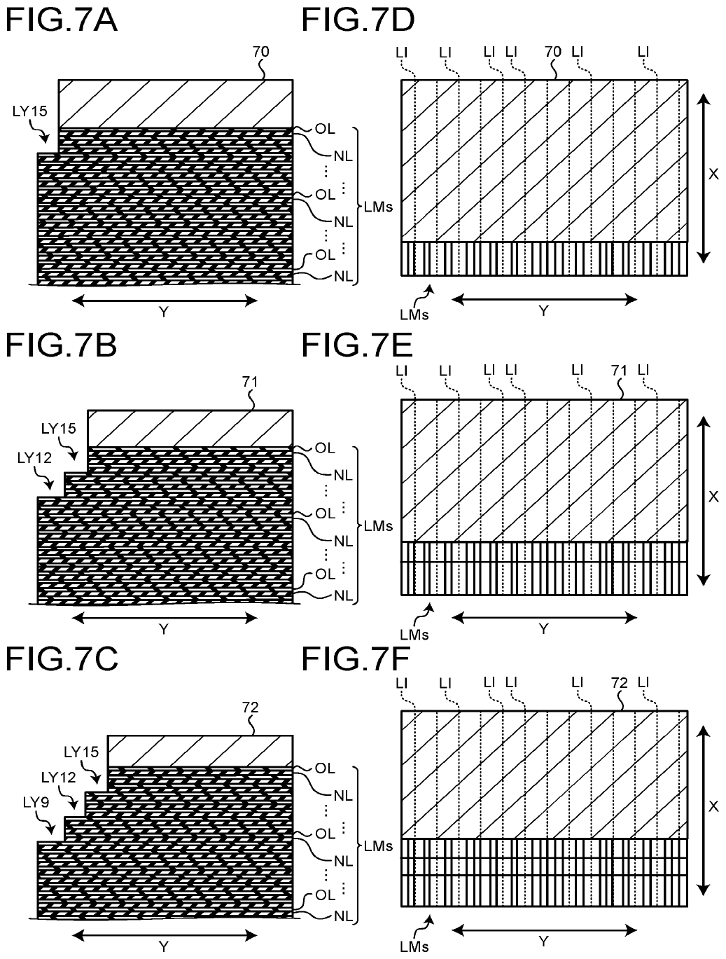

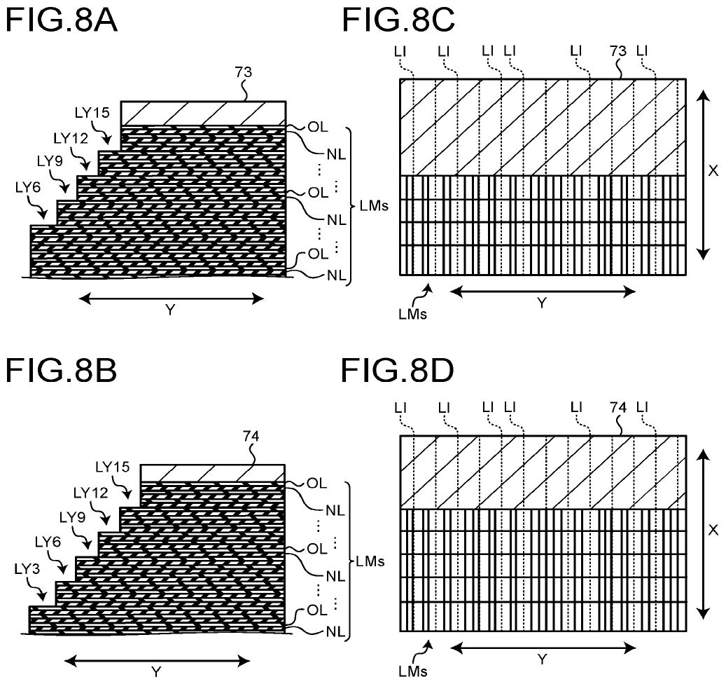

Next, an example of a method of forming GX steps will be described with reference to FIGS. 7A to 8D.

FIGS. 7A to 7C and FIGS. 8A to 8B are sectional views along the Y direction of the formation region of the stepped portion SP, and illustrate the same cross section as the cross section illustrated in FIG. 4A described above. FIGS. 7D to 7F and FIGS. 8C to 8D are top views of the formation region of the stepped portion SP.

As illustrated in FIGS. 7A and 7D, a mask pattern 70 in which a region where the lowermost step of the GX steps in the stepped portion SP is formed is exposed is formed on the stacked body LMs. The insulating layers NL and OL belonging to the three levels LY18 to LY16 are removed by etching from the surface of the stacked body LMs exposed from the mask pattern 70. As a result, the insulating layer OL belonging to the level LY15 is exposed at a portion where the lowermost step of the GX steps of the stacked body LMs is formed.

As illustrated in FIGS. 7B and 7E, an end in the X direction of the mask pattern 70 on the formation region of the stepped portion SP is retracted by slimming using oxygen plasma or the like, for example, to form a mask pattern 71. As a result, a region to be a second step from the lowermost step of the GX steps is newly exposed.

The insulating layers NL and OL belonging to the three levels LY18 to LY16 are removed by etching from the surface of the stacked body LMs newly exposed from the mask pattern 71. As a result, the insulating layer OL belonging to the level LY15 is exposed at a portion where the second step from the lowermost step of the GX steps of the stacked body LMs is formed.

In parallel with this exposure, the insulating layers NL and OL belonging to the three levels LY18 to LY16 are removed by etching from the regions from which the insulating layers NL and OL of the levels LY15 to LY13 have been removed by etching using the mask pattern 70. As a result, the insulating layer OL belonging to the level LY12 is exposed at a portion where the lowermost step of the GX steps of the stacked body LMs is formed.

As illustrated in FIGS. 7C and 7F, an end in the X direction of the mask pattern 71 on the formation region of the stepped portion SP is further retracted by slimming using oxygen plasma or the like, for example, to form a mask pattern 72. As a result, a region to be a third step from the lowermost step of the GX steps is newly exposed.

The insulating layers NL and OL belonging to the three levels LY18 to LY16 are removed by etching from the surface of the stacked body LMs newly exposed from the mask pattern 72. As a result, the insulating layer OL belonging to the level LY15 is exposed at a portion where the third step from the lowermost step of the GX steps of the stacked body LMs is formed.

In parallel with this exposure, the insulating layers NL and OL belonging to the three levels LY15 to LY13 are removed by etching from the regions from which the insulating layers NL and OL of the levels LY18 to LY16 have been removed by etching using the mask pattern 71. As a result, the insulating layer OL belonging to the level LY12 is exposed at a portion where the second step from the lowermost step of the GX steps of the stacked body LMs is formed.

In parallel with the above, the insulating layers NL and OL belonging to the three levels LY12 to LY10 are removed by etching from the regions from which the insulating layers NL and OL of the levels LY18 to LY13 have been removed by etching using the mask patterns 70 and 71. As a result, the insulating layer OL belonging to the level LY9 is exposed at a portion where the lowermost step of the GX steps of the stacked body LMs is formed.

As illustrated in FIGS. 8A and 8C, an end in the X direction of the mask pattern 72 on the formation region of the stepped portion SP is further retracted by slimming using oxygen plasma or the like, for example, to form a mask pattern 73. As a result, a region to be a fourth step from the lowermost step of the GX steps is newly exposed.

The insulating layers NL and OL belonging to the three levels LY18 to LY16 are removed by etching from the surface of the stacked body LMs newly exposed from the mask pattern 73. As a result, the insulating layer OL belonging to the level LY15 is exposed at a portion where the fourth step from the lowermost step of the GX steps of the stacked body LMs is formed.

In parallel with this exposure, the insulating layers NL and OL belonging to the three levels LY15 to LY13 are removed by etching from the regions from which the insulating layers NL and OL of the levels LY18 to LY16 have been removed by etching using the mask pattern 72. As a result, the insulating layer OL belonging to the level LY12 is exposed at a portion where the third step from the lowermost step of the GX steps of the stacked body LMs is formed.

In parallel with the above, the insulating layers NL and OL belonging to the three levels LY12 to LY10 are removed by etching from the regions from which the insulating layers NL and OL of the levels LY18 to LY13 have been removed by etching using the mask patterns 71 and 72. As a result, the insulating layer OL belonging to the level LY9 is exposed at a portion where the second step from the lowermost step of the GX steps of the stacked body LMs is formed.

In parallel with the above, the insulating layers NL and OL belonging to the three levels LY18 to LY10 are removed by etching from the regions from which the insulating layers NL and OL of the levels LY9 to LY7 have been removed by etching using the mask patterns 70 to 72. As a result, the insulating layer OL belonging to the level LY6 is exposed at a portion where the lowermost step of the GX steps of the stacked body LMs is formed.

As illustrated in FIGS. 8B and 8D, an end in the X direction of the mask pattern 73 on the formation region of the stepped portion SP is further retracted by slimming using oxygen plasma or the like, for example, to form a mask pattern 74. As a result, a region to be a fifth step from the lowermost step of the GX steps is newly exposed.

The insulating layers NL and OL belonging to the three levels LY18 to LY16 are removed by etching from the surface of the stacked body LMs newly exposed from the mask pattern 74. As a result, the insulating layer OL belonging to the level LY15 is exposed at a portion where the fifth step from the lowermost step of the GX steps of the stacked body LMs is formed.

In parallel with this exposure, the insulating layers NL and OL belonging to the three levels LY15 to LY13 are removed by etching from the regions from which the insulating layers NL and OL of the levels LY18 to LY16 have been removed by etching using the mask pattern 73. As a result, the insulating layer OL belonging to the level LY12 is exposed at a portion where the fourth step from the lowermost step of the GX steps of the stacked body LMs is formed.

In parallel with the above, the insulating layers NL and OL belonging to the three levels LY12 to LY10 are removed by etching from the regions from which the insulating layers NL and OL of the levels LY18 to LY13 have been removed by etching using the mask patterns 72 and 73. As a result, the insulating layer OL belonging to the level LY9 is exposed at a portion where the third step from the lowermost step of the GX steps of the stacked body LMs is formed.

In parallel with the above, the insulating layers NL and OL belonging to the three levels LY9 to LY7 are removed by etching from the regions from which the insulating layers NL and OL of the levels LY18 to LY10 have been removed by etching using the mask patterns 71 to 73. As a result, the insulating layer OL belonging to the level LY6 is exposed at a portion where the second step from the lowermost step of the GX steps of the stacked body LMs is formed.

In parallel with the above, the insulating layers NL and OL belonging to the three levels LY6 to LY4 are removed by etching from the regions from which the insulating layers NL and OL of the levels LY18 to LY7 have been removed by etching using the mask patterns 70 to 73. As a result, the insulating layer OL belonging to the level LY3 is exposed at a portion where the lowermost step of the GX steps of the stacked body LMs is formed.

In the above manner, the GX steps extending in the X direction are formed. In a cross section different from the cross sections illustrated in FIGS. 7A to 7C and FIGS. 8A to 8B, the height positions of the terrace surfaces at a start of processing illustrated in FIGS. 7A and 7D are different from each other. Therefore, after the processing illustrated in FIGS. 7A to 8D is completed, a plurality of rows of GX steps are formed while the arrangement of the height positions of the terrace surface in the cross section in the Y direction illustrated in FIG. 5D is maintained.

Thereafter, a plurality of memory holes (not illustrated) penetrating the stacked body LMs to reach the source line SL is formed. The memory hole is sequentially filled with a memory layer, a semiconductor layer, and the like to form the pillar PL.

A plurality of slits (not illustrated) extending in the stacking direction and the X direction of the stacked body LMs is formed, and a chemical liquid such as thermal phosphoric acid is injected from the slits to remove the insulating layer NL in the stacked body LMs. A raw material gas of a conductive material is injected through the slits, and a gap from which the insulating layer NL has been removed in the stacked body LMs is filled with the conductive material. As a result, the stacked body LM in which the plurality of word lines WL and the plurality of insulating layers OL are stacked is obtained.

As described above, the processing of forming the word line WL from the insulating layer NL is also referred to as replacement processing.

An insulating layer is formed on side walls of the slits, and the inside of the insulating layer is filled with a conductive layer to form the plate-like contact LI. However, the entire slits may be filled with an insulating layer to form a plate-like portion that does not function as the source line contact. In this case, the slits are formed exclusively for use in the replacement processing of the word line WL.

Thereafter, the insulating layer 50 and the like covering the stepped region SR are formed, and the plurality of contacts CC is formed in the stepped region SR. The upper layer interconnection or the like connected to the pillar PL, the plate-like contact LI, the contact CC, and the like via the plug is formed (see FIG. 1). The semiconductor substrate 20 in which the peripheral circuit PER including the transistor TR is formed on the surface is prepared (see FIG. 1) and bonded to the upper side of the stacked body LM.

In the above manner, the semiconductor memory device 1 according to the embodiment is manufactured.

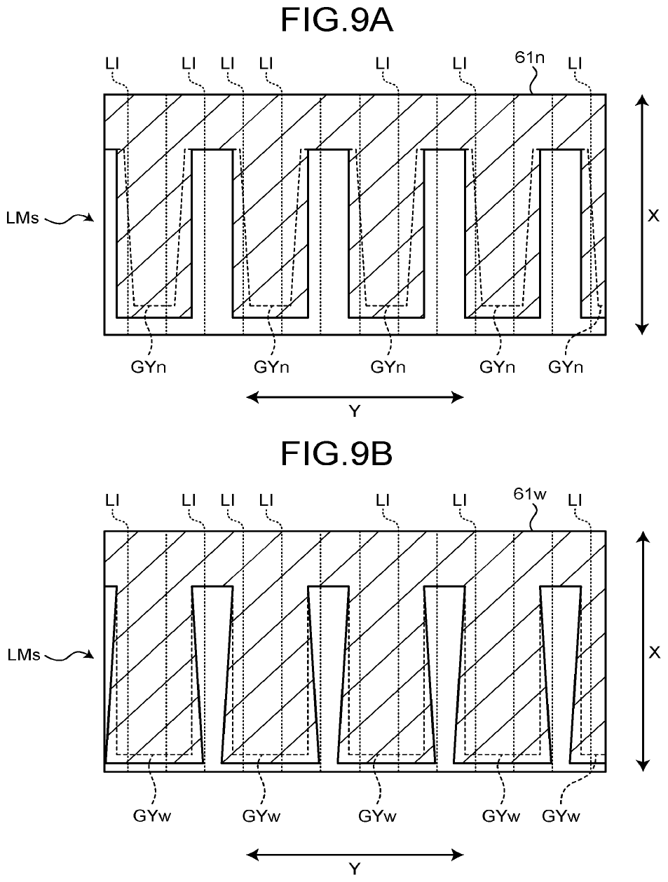

As described above, when the GY steps are formed, the mask patterns 61 to 63 having a plurality of patterns extending in the X direction at predetermined intervals in the Y direction are used. A plurality of extending portions of the mask patterns 61 to 63 is subjected to correction called optical proximity correction (OPC) in anticipation of a dimensional conversion difference generated in the GY steps at the time of forming the GX steps later. Such correction is illustrated in FIGS. 9A and 9B.

FIGS. 9A and 9B are top views of the stacked body LMs for describing a correction example of the mask pattern 61 used at the time of forming GY steps according to the embodiment. FIG. 9A is an example of a mask pattern 61n that has not been corrected, and FIG. 9B is an example of a mask pattern 61w that has been corrected.

When the GX steps are formed after the formation of the GY steps, the processing proceeds from the lowermost step toward the uppermost step in the X direction of the stepped portion SP. Therefore, the time to be exposed to the plasma or the chemical liquid at the time of etching becomes longer toward the lowermost step in the X direction, and the dimensional conversion difference of each component of the formed GY steps becomes larger.

As illustrated in FIG. 9A, when the correction is not performed, widths in the Y direction of the plurality of extending portions of the mask pattern 61n are constant in the X direction. In the GY steps formed by using such a mask pattern 61n, a width of each configuration in the Y direction in the X direction is also constant before the formation of the GX steps. However, after the formation of the GX steps, the width in the Y direction of each configuration GYn of the GY steps becomes narrower as the dimensional conversion difference becomes larger toward the lowermost step. The lowermost step side of each configuration GYn of the GY steps retreats to the upper layer side.

As illustrated in FIG. 9B, on the basis of a theory of the optical proximity correction, the widths in the Y direction of the plurality of extending portions included in the mask pattern 61w are corrected so as to increase toward the lowermost step. The mask pattern 61w is formed in a state where the end in the X direction on the lowermost step side protrudes in a direction away from the upper layer side. In the GY steps formed by using such a mask pattern 61w, the width of each configuration in the Y direction also increases toward the lowermost step before the formation of the GX steps. After the formation of the GX steps, the width in the Y direction of each configuration GYw of the GY steps ideally becomes constant in the X direction since the dimensional conversion difference becomes larger toward the lowermost step. An end on the lowermost step side of each configuration GYw of the GY steps is disposed at a desired position in the X direction.

### Overview

In a semiconductor memory device such as a three-dimensional non-volatile memory, in order to electrically draw out word lines stacked in a plurality of steps, for example, a stepped portion in which the word lines are processed into a stepped shape is provided. In order to shorten the length in the X direction, such a stepped portion may have a structure of a multiple rows of steps such as a three-row steps. The structure of a plurality of rows of steps is obtained, for example, by forming a mask pattern in line-symmetry in the Y direction with respect to each of the plurality of plate-like contacts and processing the stacked body.

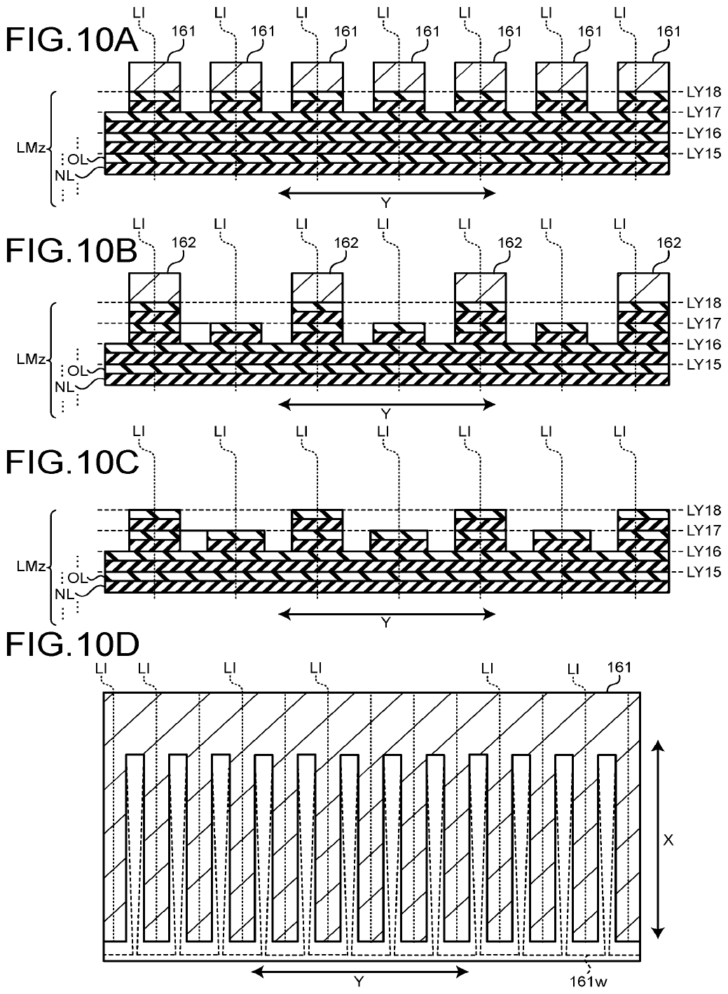

FIGS. 10A to 10D are sectional views in the Y direction illustrating an example of a procedure of a method of forming GY steps according to a comparative example. As illustrated in FIG. 10A, a mask pattern 161 line-symmetric in the Y direction with respect to a boundary of each region divided by a plurality of plate-like contacts LI to be formed later is formed at the boundary of these regions, and an exposed portion of a stacked body LMz is etched. As illustrated in FIG. 10B, a mask pattern 162 line-symmetric in the Y direction with respect to a boundary of the plurality of regions is formed at every other boundary of these regions, and an exposed portion of a stacked body LMz is etched. As illustrated in FIG. 10C, as described above, three terrace surfaces having different height positions are formed in each of the plurality of regions so as to be arranged in line-symmetry in the Y direction with respect to the boundary of these regions.

Here, the mask pattern 161 or the like may be subjected to correction such as the OPC in anticipation of a dimensional conversion difference generated during processing of the GX steps. However, as the number of stacked word lines increases, there is a concern that the mask pattern 161 reaches a limit of correction. As illustrated in FIG. 10D, as compared to a case where mask pattern 161 is not corrected, in a mask pattern 161w after correction, adjacent patterns in the Y direction are excessively close to each other, and there is a possibility that a sufficient resolution cannot be obtained at a time of developing the mask pattern 161w, for example, exceeding a limit of development.

In the method of manufacturing the semiconductor memory device 1 according to the embodiment, the mask pattern 61 is formed by shifting the center position in the Y direction toward the region AR1 with respect to the boundary between the regions AR1 and AR2. The mask pattern 62 is formed by shifting the center position in the Y direction toward the region AR2 with respect to the boundary between the regions AR1 and AR2.

In the semiconductor memory device 1 according to the embodiment, in the above manufacturing method, in the regions AR1 and AR2, the height positions of the plurality of terrace surfaces are arranged in line-asymmetry with respect to the plate-like contact LI that divides the regions AR1 and AR2 when viewed in a cross section along the Y direction.

As described above, by changing a layout of the mask patterns 61 and 62, a distance between the patterns arranged at a predetermined cycle in the Y direction can be sufficiently secured, and a correction margin of the mask patterns 61 and 62 can be secured. That is, a correctable range of the mask patterns 61 and 62 can be expanded without exceeding the limit of development of the mask patterns 61 and 62, and a processing difficulty of the stepped portion SP can be reduced.

In the semiconductor memory device 1 according to the embodiment, when viewed in a cross section along the Y direction, each of the regions AR1 to AR5 has three terrace surfaces in which the word lines WL continuous in the stacking direction of the stacked body LM serve as the terrace surfaces. In the stepped portion SP, the number in levels of the word lines WL as the terrace surfaces arrayed in the X direction increases by three.

In this manner, since the stepped portion SP has a structure of a plurality of rows of steps such as a three-row steps, for example, the number in levels of the word lines WL as the terrace surfaces arrayed in the X direction can be increased by three, and the length of the stepped portion SP in the X direction can be shortened. This configuration facilitates downsizing of the semiconductor memory device 1, an increase in memory capacity, or the like.

### Modification

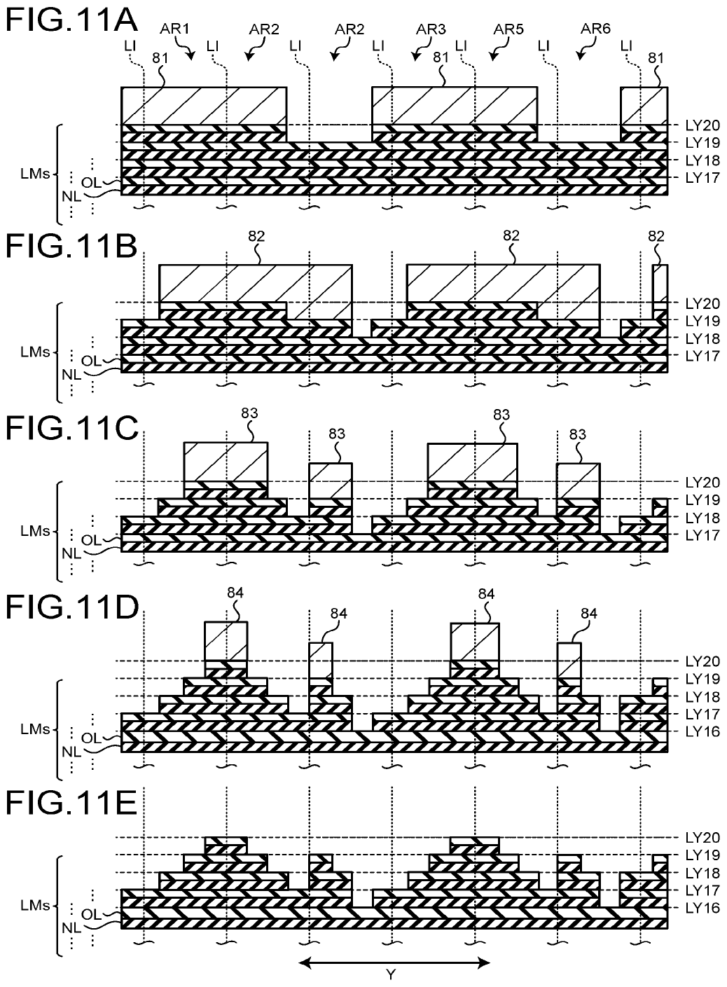

Next, a semiconductor memory device according to a modification of the embodiment will be described with reference to FIGS. 11A to 11E. The semiconductor memory device according to the modification is different from the semiconductor memory device according to the above embodiment in that four rows of GX steps are provided in one region divided by the plate-like contact LI.

FIGS. 11A to 11E are sectional views sequentially exemplifying a part of a procedure of a method of manufacturing the semiconductor memory device according to the modification of the embodiment. FIGS. 11A to 11E are examples in a case where the configuration of the embodiment is applied to the stacked body LMs including 20 insulating layers NL. That is, in the stacked body LMs according to the modification, the uppermost insulating layer NL belongs to the level LY20. Note that, FIGS. 11A to 11E illustrate only the configuration on the upper layer side including the uppermost insulating layer NL of the stacked body LMs.

As illustrated in FIG. 11A, in the method of manufacturing the semiconductor memory device according to the modification as well, a mask pattern 81 as a first mask pattern that covers a region where the pillars PL and the like of the stacked body LMs are to be formed is formed on the stacked body LMs.

The mask pattern 81 is formed across the regions AR3 to AR5 so as to have a width corresponding to two of the regions AR3 to AR5 in the Y direction in a region where the stepped portion according to the modification is to be formed. The mask pattern 81 is formed such that a center position in the Y direction is shifted toward the region AR4 with respect to the plate-like contact LI to be formed at a boundary between the regions AR4 and AR5, that is, between the regions AR4 and AR5.

As a result, the mask pattern 81 formed across the regions AR3 to AR5 is formed at a boundary with the region AR4 on the region AR3 to have a width corresponding to one terrace surface in the Y direction, the width being a width that the stepped portion finally has. As described above, since the stepped portion according to the modification has a structure of four rows of steps, the width of one terrace surface in the Y direction is, for example, about a quarter of one region AR3 or the like. The mask pattern 81 is formed to cover the entire region AR4. The mask pattern 81 is formed at a boundary with the region AR4 on the region AR5 to have a width corresponding to three terrace surfaces in the Y direction.

Similarly, the mask pattern 81 includes the region AR2 and is formed across three regions arrayed in a direction opposite to the region AR3 so as to have a width corresponding to two of the regions AR2 and the like in the Y direction. The mask pattern 81 is formed such that a center position in the Y direction is shifted toward the region AR1 with respect to the plate-like contact LI to be formed at a boundary between the regions AR1 and AR2, that is, between the regions AR1 and AR2.

As a result, the mask pattern 81 formed across the three regions including the region AR2 is formed at a boundary of the region AR1 on a region adjacent to the region AR1 on an opposite side of the region AR2 with a width in the Y direction of one terrace surface that the stepped portion finally has. The mask pattern 81 is formed to cover the entire region AR1. The mask pattern 81 is formed at a boundary with the region AR1 on the region AR2 to have a width corresponding to three terrace surfaces in the Y direction.

In this manner, in the region where the stepped portion according to the modification is formed, the mask pattern 81 is formed to have a periodic pattern in the Y direction.

A pair of insulating layers NL and OL belonging to the level LY20 is removed by etching or the like from the surface of the stacked body LMs exposed from the mask pattern 81 formed as described above, and the insulating layer OL belonging to the level LY19 is exposed. Thereafter, the mask pattern 81 is removed by ashing using oxygen plasma or the like.

As illustrated in FIG. 11B, similarly to the mask pattern 81, a mask pattern 82 as a second mask pattern that covers a region where the pillars PL and the like of the stacked body LMs are to be formed is formed on the stacked body LMs.

The mask pattern 82 is formed across the regions AR4 to AR6 so as to have a width corresponding to two or more and less than three of the regions AR4 to AR6 in the Y direction in the region where the stepped portion according to the modification is to be formed. The mask pattern 82 is formed such that a center position in the Y direction is shifted toward the region AR5 with respect to the plate-like contact LI to be formed at a boundary between the regions AR4 and AR5, that is, between the regions AR4 and AR5.

As a result, the mask pattern 82 formed across the regions AR4 to AR6 is formed at a boundary with the region AR5 on the region AR4 to have a width corresponding to three terrace surfaces in the Y direction. The mask pattern 82 is formed to cover the entire region AR5. The mask pattern 82 is formed at a boundary with the region AR5 on the region AR6 to have a width corresponding to two terrace surfaces in the Y direction.

Similarly, the mask pattern 82 is formed across the regions AR1 to AR3 so as to have a width corresponding to two or more and less than three of the regions AR1 to AR3 in the Y direction. In this case, the mask pattern 82 is also formed such that a center position in the Y direction is shifted toward the region AR2 with respect to the plate-like contact LI to be formed at a boundary between the regions AR1 and AR2, that is, between the regions AR1 and AR2.

As a result, the mask pattern 82 formed across the regions AR1 to AR3 is formed at a boundary with the region AR2 on the region AR1 to have a width corresponding to three terrace surfaces in the Y direction, the width being a width that the stepped portion finally has. The mask pattern 82 is formed to cover the entire region AR2. The mask pattern 82 is formed at a boundary with the region AR2 on the region AR3 to have a width corresponding to two terrace surfaces in the Y direction.

In this manner, in the region where the stepped portion according to the modification is formed, the mask pattern 82 is also formed to have a periodic pattern in the Y direction.

A pair of insulating layers NL and OL is etched from the surface of the stacked body LMs exposed from the mask pattern 81 formed as described above.

At this time, the insulating layers NL and OL of the level LY20 are removed from a partial region newly exposed after the formation of the mask pattern 82 in the regions AR3, AR4, and the like between the mask patterns 82 having the periodic pattern in the Y direction, and the insulating layer OL belonging to the level LY19 is exposed. In the regions AR3, AR4, and the like between the mask patterns 82, the insulating layers NL and OL of the level LY19 below the level LY20 are removed from a partial region from which the insulating layers NL and OL of the level LY20 have been removed by etching using the mask pattern 81, and the insulating layer OL belonging to the level LY18 is exposed.

As a result, two or three terrace surfaces having different heights are formed in each of the regions AR1 to AR6 and the like. At this time, for example, in the regions AR1 and AR2, the height positions of the plurality of terrace surfaces are arranged in line-symmetry with respect to the boundary of the regions AR1 and AR2. For example, in the regions AR4 and AR5, the height positions of the plurality of terrace surfaces are arranged in line-symmetry with respect to the boundary of the regions AR4 and AR5.

However, the width of the terrace surface in the Y direction at this time does not necessarily coincide with the width of the terrace surface in the Y direction that the stepped portion finally has. The terrace surface at this time has the same height over the entire region to be the stepped portion in the X direction.

Thereafter, the mask pattern 82 is removed by ashing using oxygen plasma or the like.

As illustrated in FIG. 11C, mask patterns 83 as third to fourth mask patterns are formed on the stacked body LMs. The mask pattern 83 covers a region where the pillar PL and the like of the stacked body LMs are formed, similarly to the mask patterns 81 and 82. In a region where the stepped portion is to be formed, the mask patterns 83 extend in the X direction at predetermined intervals in the Y direction at a different position from the mask patterns 81 and 82.

Specifically, the mask pattern 83 as the third mask pattern is formed across the regions AR4 and AR5, for example. At this time, the mask pattern 83 is formed in a partial region of the regions AR4 and AR5 such that the center position in the Y direction coincides with a boundary between the regions AR4 and AR5, that is, the plate-like contact LI to be formed between the regions AR4 and AR5.

As a result, the mask pattern 83 formed across the regions AR4 and AR5 is formed at a boundary with the region AR5 on the region AR4 to have a width corresponding to two terrace surfaces in the Y direction, the width being a width that the stepped portion finally has. The mask pattern 83 is formed at a boundary with the region AR4 on the region AR5 to have a width corresponding to two terrace surfaces in the Y direction.

Similarly, the mask pattern 83 is formed across the regions AR1 and AR2, for example. At this time, the mask pattern 83 is formed in a partial region of the regions AR1 and AR2 such that the center position in the Y direction coincides with a boundary between the regions AR1 and AR2, that is, the plate-like contact LI to be formed between the regions AR1 and AR2.

As a result, the mask pattern 83 formed across the regions AR1 and AR2 is formed at a boundary with the region AR2 on the region AR1 to have a width corresponding to two terrace surfaces in the Y direction, the width being a width that the stepped portion finally has. The mask pattern 83 is formed at a boundary with the region AR1 on the region AR2 to have a width corresponding to two terrace surfaces in the Y direction.

In this manner, in the region where the stepped portion is formed, the mask pattern 83 as the third mask pattern is also formed to have a periodic pattern in the Y direction.

The mask pattern 83 as the fourth mask pattern is formed to cover, for example, a part of the region AR3 on a side in contact with the region AR2. At this time, the mask pattern 83 is formed at a boundary with the region AR2 on the region AR3 to have a width corresponding to two terrace surfaces in the Y direction, the width being a width that the stepped portion finally has.

Similarly, the mask pattern 83 is formed to cover, for example, a part of the region AR6 on a side in contact with the region AR5. At this time, the mask pattern 83 is formed at a boundary with the region AR5 on the region AR6 to have a width corresponding to two terrace surfaces in the Y direction, the width being a width that the stepped portion finally has.

In the region where the stepped portion is formed, the mask pattern 83 as the fourth mask pattern is also formed to have a periodic pattern in the Y direction on one side in the Y direction of the mask pattern 83 as the third mask pattern formed at the boundary of the regions AR1 and AR2, the boundary of the regions AR4 and AR5, and the like.

A pair of insulating layers NL and OL is etched from the surface of the stacked body LMs exposed from the mask pattern 83 formed as described above.

At this time, the insulating layers NL and OL of the level LY20 are removed from a partial region newly exposed after the formation of the mask pattern 83 in each region, and the like between the mask patterns 83 disposed at predetermined intervals in the Y direction, and the insulating layer OL belonging to the level LY19 is exposed.

In each region, and the like between the mask patterns 83, the insulating layers NL and OL of the level LY19 below the level LY20 are removed from a partial region from which the insulating layers NL and OL of the level LY20 have been removed by etching using the mask pattern 82, and the insulating layer OL belonging to the level LY18 is exposed.

In each region between the mask patterns 83, the insulating layers NL and OL of the level LY18 below the level LY19 are removed from a partial region from which the insulating layers NL and OL of the levels LY20 and LY19 have been removed by etching using the mask patterns 81 and 82, and the insulating layer OL belonging to the level LY17 is exposed.

Thereafter, the mask pattern 83 is removed by ashing using oxygen plasma or the like.

As illustrated in FIG. 11D, mask patterns 84 as fifth and sixth mask patterns are formed on the stacked body LMs. The mask pattern 84 covers a region where the pillar PL and the like of the stacked body LMs are formed, similarly to the mask patterns 81 to 83. In a region where the stepped portion is to be formed, the mask patterns 84 extend in the X direction at predetermined intervals in the Y direction at a different position from the mask pattern 84.

Specifically, the mask pattern 84 as the sixth mask pattern is formed across the regions AR4 and AR5, for example. At this time, the mask pattern 84 is formed in a partial region of the regions AR4 and AR5 such that the center position in the Y direction coincides with a boundary between the regions AR4 and AR5, that is, the plate-like contact LI to be formed between the regions AR4 and AR5.

As a result, the mask pattern 84 formed across the regions AR4 and AR5 is formed at a boundary with the region AR5 on the region AR4 to have a width corresponding to one terrace surface in the Y direction, the width being a width that the stepped portion finally has. The mask pattern 84 is formed at a boundary with the region AR4 on the region AR5 to have a width corresponding to one terrace surface in the Y direction.

Similarly, the mask pattern 84 as the fifth mask pattern is formed across the regions AR1 and AR2, for example. At this time, the mask pattern 84 is formed in a partial region of the regions AR1 and AR2 such that the center position in the Y direction coincides with a boundary between the regions AR1 and AR2, that is, the plate-like contact LI to be formed between the regions AR1 and AR2.

As a result, the mask pattern 84 formed across the regions AR1 and AR2 is formed at a boundary with the region AR2 on the region AR1 to have a width corresponding to one terrace surface in the Y direction, the width being a width that the stepped portion finally has. The mask pattern 84 is formed at a boundary with the region AR1 on the region AR2 to have a width corresponding to one terrace surface in the Y direction.

The mask pattern 84 is formed to cover, for example, a part of the region AR3 on a side in contact with the region AR2. At this time, the mask pattern 83 is formed at a boundary with the region AR2 on the region AR3 to have a width corresponding to one terrace surface in the Y direction, the width being a width that the stepped portion finally has.

Similarly, the mask pattern 84 is formed to cover, for example, a part of the region AR6 on a side in contact with the region AR5. At this time, the mask pattern 84 is formed at a boundary with the region AR5 on the region AR6 to have a width corresponding to one terrace surface in the Y direction, the width being a width that the stepped portion finally has.

In the region where the stepped portion is formed, the mask patterns 84 are also formed at predetermined intervals in the Y direction similarly to the mask patterns 83.

A pair of insulating layers NL and OL is etched from the surface of the stacked body LMs exposed from the mask pattern 84 formed as described above.

At this time, the insulating layers NL and OL of the level LY20 are removed from a partial region newly exposed after the formation of the mask pattern 84 in each region, and the like between the mask patterns 84 disposed at predetermined intervals in the Y direction, and the insulating layer OL belonging to the level LY19 is exposed.

In each region, and the like between the mask patterns 84, the insulating layers NL and OL of the level LY19 below the level LY20 are removed from a partial region from which the insulating layers NL and OL of the level LY20 have been removed by etching using the mask pattern 83, and the insulating layer OL belonging to the level LY18 is exposed.

In each region between the mask patterns 84, the insulating layers NL and OL of the level LY18 below the level LY19 are removed from a partial region from which the insulating layers NL and OL of the levels LY20 and LY19 have been removed by etching using the mask patterns 82 and 83, and the insulating layer OL belonging to the level LY17 is exposed.

In each region between the mask patterns 84, the insulating layers NL and OL of the level LY17 below the level LY18 are removed from a partial region from which the insulating layers NL and OL of the levels LY20 to LY18 have been removed by etching using the mask patterns 81 to 83, and the insulating layer OL belonging to the level LY16 is exposed.

As illustrated in FIG. 11E, the mask pattern 84 is removed by ashing using oxygen plasma or the like. As a result, the shape of the GY steps that the stepped portion finally has is formed in a cross section along the Y direction. Thereafter, the stepped portion according to the modification is formed by forming the GX steps by a procedure similar to the procedure of the above embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of conductive layers and a plurality of insulating layers are alternately stacked one by one;
a stepped portion in which the plurality of conductive layers is processed into a stepped shape; and
a plurality of plate-like portions that extends in the stacked body in a stacking direction of the stacked body and a first direction intersecting the stacking direction and divides the stacked body and the stepped portion of the stacked body in a second direction intersecting the stacking direction and the first direction, wherein
the stepped portion includes first to third regions that are divided by the plurality of plate-like portions and are adjacent in an order of the first to third regions in the second direction, and
when viewed in a cross section along the second direction,
each of the first to third regions has a plurality of terrace surfaces arrayed in the second direction and having different height positions,
in the first and second regions, the height positions of the plurality of terrace surfaces are arranged in line-symmetry with respect to a plate-like portion dividing the first and second regions among the plurality of plate-like portions, and
in the second and third regions, the height positions of the plurality of terrace surfaces are arranged in line-asymmetry with respect to a plate-like portion dividing the second and third regions among the plurality of plate-like portions.

2. The semiconductor memory device according to claim 1, wherein
the stepped portion further includes a fourth region that is divided by the plurality of plate-like portions and is adjacent to the third region on an opposite side of the second region, and
when viewed in a cross section along the second direction,
the fourth region has a plurality of terrace surfaces arrayed in the second direction and having different height positions, and
in the third and fourth regions, the height positions of the plurality of terrace surfaces are arranged in line-asymmetry with respect to a plate-like portion dividing the third and fourth regions among the plurality of plate-like portions.

3. The semiconductor memory device according to claim 2, wherein
the stepped portion further includes a fifth region that is divided by the plurality of plate-like portions and is adjacent to the fourth region on an opposite side of the third region, and
when viewed in a cross section along the second direction,
the fifth region has a plurality of terrace surfaces arrayed in the second direction and having different height positions, and
in the fourth and fifth regions, the height positions of the plurality of terrace surfaces are arranged in line-symmetry with respect to a plate-like portion dividing the fourth and fifth regions among the plurality of plate-like portions.

4. The semiconductor memory device according to claim 3, wherein
the stepped portion further includes a sixth region that is divided by the plurality of plate-like portions and is adjacent to the first region on an opposite side of the second region, and
when viewed in a cross section along the second direction,
an arrangement of the height positions of the plurality of terrace surfaces in the sixth region and the first to third regions is different from an arrangement of the height positions of the plurality of terrace surfaces in the third to fifth regions.

5. The semiconductor memory device according to claim 3, wherein
when viewed in the cross section along the second direction,
each of the first to fifth regions has three terrace surfaces in which conductive layers continuous in the stacking direction among the plurality of conductive layers serve as the terrace surfaces.

6. The semiconductor memory device according to claim 3, wherein
in the stepped portion, the number in levels of conductive layers being the terrace surfaces arrayed in the first direction among the plurality of conductive layers increases by three.

7. The semiconductor memory device according to claim 3, wherein
the stepped portion further includes a sixth region that is divided by the plurality of plate-like portions and is adjacent to the first region on an opposite side of the second region, and
when viewed in a cross section along the second direction,
an arrangement of the height positions of the plurality of terrace surfaces in the sixth region and the first to third regions is equal to an arrangement of the height positions of the plurality of terrace surfaces in the third to fifth regions.

8. The semiconductor memory device according to claim 3, wherein
when viewed in the cross section along the second direction,
each of the first to fifth regions has four terrace surfaces in which conductive layers continuous in the stacking direction among the plurality of conductive layers serve as the terrace surfaces.

9. The semiconductor memory device according to claim 3, wherein
in the stepped portion, the number in levels of conductive layers being the terrace surfaces arrayed in the first direction among the plurality of conductive layers increases by four.

10. A method of manufacturing a semiconductor memory device, the method comprising:
forming a stacked body in which a plurality of first insulating layers and a plurality of second insulating layers are alternately stacked one by one;
forming a stepped portion in which the plurality of first insulating layers is processed into a stepped shape;
forming a plurality of plate-like portions that extends in the stacked body in a stacking direction of the stacked body and a first direction intersecting the stacking direction and divides the stacked body and the stepped portion of the stacked body in a second direction intersecting the stacking direction and the first direction;
when the stepped portion is formed,
forming a first mask pattern across first to third regions that are to be divided by the plurality of plate-like portions and are adjacent in an order of the first to third regions in the second direction, the first mask pattern being formed so as to have a width in the second direction that is less than a width of the first to third regions in the second direction;
removing a pair of first and second insulating layers of the plurality of first and second insulating layers from a surface of the stacked body exposed from the first mask pattern;
after removing the first mask pattern, forming a second mask pattern across the second and third regions and a fourth region adjacent to the third region on an opposite side of the second region, the second to fourth regions being to be divided by the plurality of plate-like portions, the second mask pattern being formed so as to have a width in the second direction that is less than a width of the second to fourth regions in the second direction;
removing the pair of first and second insulating layers from a surface of the stacked body exposed from the second mask pattern;
when the first mask pattern is formed,
forming the first mask pattern by shifting a center position in the second direction toward the second region with respect to a boundary between the second and third regions; and
when the second mask pattern is formed,
forming the second mask pattern by shifting a center position in the second direction toward the third region with respect to the boundary between the second and third regions.

11. The method of manufacturing a semiconductor memory device according to claim 10, wherein
after the stacked body exposed from the second mask pattern is processed,
each of the first to fourth regions has a plurality of terrace surfaces arrayed in the second direction and having different height positions, and
in the second and third regions, the height positions of the plurality of terrace surfaces are arranged in line-symmetry with respect to the boundary between the second and third regions.

12. The method of manufacturing a semiconductor memory device according to claim 11, further comprising:
after removing the second mask pattern, forming a third mask pattern across the second and third regions so as to cover a part of the second and third regions;
removing the pair of first and second insulating layers from a surface of the stacked body exposed from the third mask pattern; and
when the third mask pattern is formed,
forming the third mask pattern such that a center position in the second direction coincides with the boundary between the second and third regions.

13. The method of manufacturing a semiconductor memory device according to claim 12, wherein
after the stacked body exposed from the second mask pattern is processed,
when viewed in a cross section along the second direction, in the first to fourth regions, the height positions of the plurality of terrace surfaces are arranged in line-symmetry with respect to the boundary between the second and third regions.

14. The method of manufacturing a semiconductor memory device according to claim 12, further comprising:
when the third mask pattern is formed,
forming a fourth mask pattern so as to cover a part of the first region on a side in contact with the second region;
forming a fifth mask pattern so as to cover a part of the fourth region on a side in contact with the third region; and
when the stacked body exposed from the third mask pattern is processed,
removing the pair of first and second insulating layers from a surface of the stacked body exposed from the fourth and fifth mask patterns.

15. The method of manufacturing a semiconductor memory device according to claim 14, further comprising
when the fourth and fifth mask patterns are formed,
arranging the fourth and fifth mask patterns in line-symmetry in the second direction with respect to the boundary between the second and third regions.

16. The method of manufacturing a semiconductor memory device according to claim 15, wherein
after the stacked body exposed from the third to fifth mask patterns is processed,
in the first to fourth regions, the height positions of the plurality of terrace surfaces are arranged in line-symmetry with respect to the boundary between the second and third regions.

17. The method of manufacturing a semiconductor memory device according to claim 12, wherein
after the stacked body exposed from the second mask pattern is processed,
when viewed in a cross section along the second direction, in the first to fourth regions, the height positions of the plurality of terrace surfaces are arranged in line-asymmetry with respect to the boundary between the second and third regions.

18. The method of manufacturing a semiconductor memory device according to claim 12, further comprising:
when the third mask pattern is formed,
forming a fourth mask pattern so as to cover a part of the fourth region on a side in contact with the third region; and
when the stacked body exposed from the third mask pattern is processed,
removing the pair of first and second insulating layers from a surface of the stacked body exposed from the fourth mask pattern.

19. The method of manufacturing a semiconductor memory device according to claim 12, further comprising:
after removing the third mask pattern, forming a fifth mask pattern across the second and third regions so as to cover a part of the second and third regions;
removing the pair of first and second insulating layers from a surface of the stacked body exposed from the fifth mask pattern; and
when the fifth mask pattern is formed,
forming the fifth mask pattern such that a center position in the second direction coincides with the boundary between the second and third regions.

20. The method of manufacturing a semiconductor memory device according to claim 19, further comprising:
when the fifth mask pattern is formed,
forming a sixth mask pattern so as to cover a part of the fourth region on a side in contact with the third region; and
when the stacked body exposed from the fifth mask pattern is processed,
removing the pair of first and second insulating layers from a surface of the stacked body exposed from the sixth mask pattern.
